(19) United States
(12) Patent Application Publication
(10) Pub. No.: US 2008/0158821 A1
(43) Pub. Date: Jul. 3, 2008

(54) Printed Board Assembly with Improved Heat Dissipation

(75) Inventor: Johan Sandwall, Floda (SE)

Correspondence Address: ERICSSON INC., 6300 LEGACY DRIVE, M/S EVR 1-C-11, PLANO, TX, 75024, US

(73) Assignee: TELEFONAKTIEBOLAGET LM ERICSSON (PUBL), Stockholm (SE)

(21) Appl. No.: 11/720,403

(22) PCT Filed: Nov. 30, 2004
(86) PCT No.: PCT/SE04/01760

§ 371 Date: May 29, 2007

(51) Int. Cl. H05K 7/20

(52) U.S. Cl. 361/704

(57) ABSTRACT

A multi-layer printed board assembly (PBA) with improved heat dissipation characteristics. The PBA includes a cooling component, which extends essentially perpendicularly through the layers of the PBA. A first end of the cooling component contacts a cooling structure external to the PBA. An electronic component is surface mounted at least partially over a second end of the cooling component. The cooling component transports heat from the electronic component through the PBA to the external cooling structure.

### TECHNICAL FIELD

The present invention discloses a printed board assembly, a PBA, which comprises a first support layer with a first main surface, and a first layer of a conducting material arranged in a first pattern. The PBA of the invention additionally comprises a first electronics component and a first cooling component for transporting heat from the first electronics component to a cooling structure.

### BACKGROUND ART

Many electronics components that are used in contemporary printed board assemblies, PBA:s, generate a great deal of heat. This is especially true of, for example, such components as high power amplifiers (HPA:s) and power transistors.

To cool the PBA:s then becomes a problem, to which many solutions have been presented. Solutions which are known at present often include production steps which necessitate manual labour, or use via holes.

Some problems with these known solutions are that via holes can only dissipate a limited amount of heat, and manual labour will cause the product to become rather expensive.

### DISCLOSURE OF THE INVENTION

There is thus a need for a PBA which can dissipate heat from, for example, an HPA in a manner which is more efficient than solutions known today. It should be possible to produce such a PBA without as little manual labour as possible.

These needs are addressed by the present invention in that it discloses a printed board assembly, a PBA, comprising a first support layer which has a first main surface and a first layer of a conducting material arranged in a first pattern.

The PBA of the invention additionally comprises a first electronics component, and a first cooling component for transporting heat from the first electronics component to a cooling structure.

According to the invention, the first electronics component is surface mounted on the PBA, and is arranged at least partially over the first cooling structure, and the first cooling component is arranged integrally in the PBA, in a direction which is essentially perpendicular to the main surface of the first support layer.

Additionally, the first cooling component is arranged in the PBA such means as, for example, soldering or gluing.

The electronics component can be surface mounted by such means as, for example, gluing, soldering or the application of pressure.

Thus, by means of the invention, and as will become evident from the following detailed description, a PBA is obtained which has a cooling structure with a higher degree of performance than known such structures. The PBA of the invention is also easier to manufacture by automated means than known PBA:s.

### BRIEF DESCRIPTION OF THE DRAWINGS

The invention will be described in more detail in the following, with reference to the appended drawings, in which

FIG. 1 shows a cross-sectional view from the side of a basic PBA according to the invention, and

FIG. 2 shows a cooling structure for use in a PBA of the invention, and

FIG. 3 shows a cross-sectional view from the side of a PBA according to the invention, and

FIG. 4 shows a flowchart of some of the major steps in a production method according to the invention.

### EMBODIMENTS

Initially, it should be pointed out that in this description, the term “Printed Board Assembly” will be used throughout to describe the invention. Generally, the term Printed Circuit Board, PCB, is used to denote a circuit board without any components mounted on it, while the term Printed Board Assembly, PBA, is generally used to described the combination of a PCB and one or several components which are arranged on the PCB. In order not to obscure the description, the term PBA is used consistently in the text.

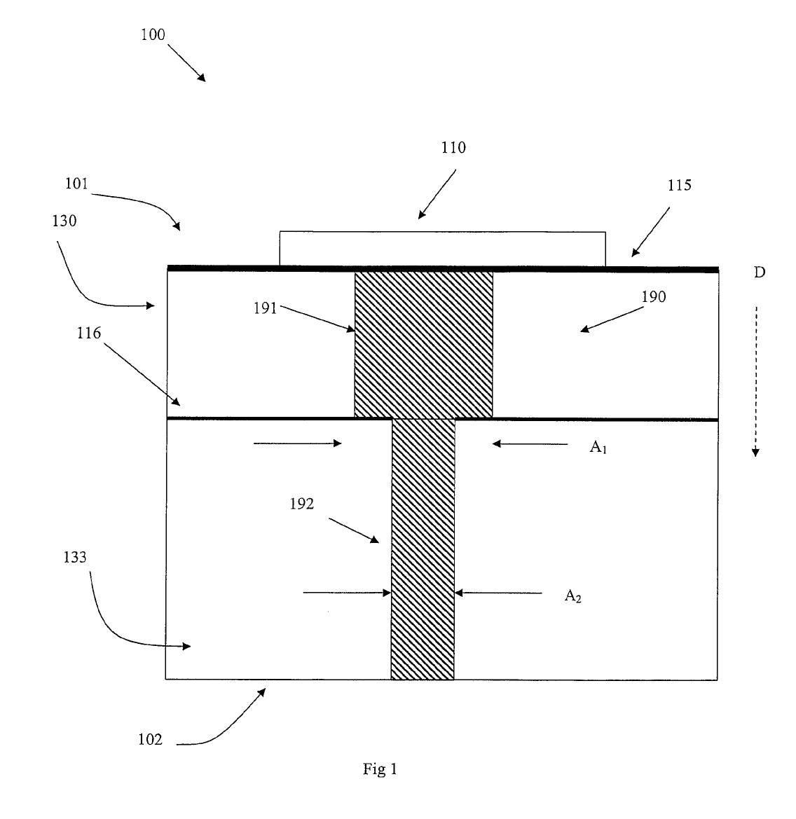

FIG. 1 shows a basic and simplified PBA 100 according to the invention, seen in a cross-sectional view from the side. It should be emphasized here that FIG. 1 does not show how the PBA of the invention is to be manufactured, nor is FIG. 1 intended to show all of the details of the PBA of the invention, FIG. 1 serves mainly to illustrate a principle behind the invention.

Thus as, implied by FIG. 1, the PBA 100 of the invention has a first main surface, the upper surface 101, and a second main surface, the lower surface 102.

According to the invention, the PBA 100 comprises a first cooling component 190, arranged integrally in the PBA, as well as a first component 110, suitably an electronics component such as a high power amplifier (HPA) or a power transistor. The first component 110 thus generates a great deal of heat, which needs to be transported away from the PBA.

Preferably, the first cooling component 190 is manufactured in a material which has very good properties when it comes to transporting heart, such as copper or brass or similar metals or metal alloys.

As can be seen in FIG. 1, the cooling component 190 has a first main direction of extension, indicated by the arrow D, and has a first section 191 with a first cross sectional area A₁, and a second section area 192 with a second cross sectional area A₂. The reason for the different cross sectional areas will become apparent in the following explanations. In FIG. 1, A₁ is shown as being larger than A₂, but as will be realized later, the case can also be the reverse.

One of the purposes of the invention is to obtain a PBA with an integrated cooling component which can be manufactured essentially without any manual labour. In order to achieve this purpose, the PBA is structured in the following way: the main body 130 of the PBA is a supporting laminate of a known kind, such as FR4.

The main body 130 is prepared for receiving the first cooling component 190 by a hole or a “window” being made in main body. The hole is a through-hole, i.e. it extends from the first main surface 101 of the main body to the second main surface 102. During a first distance from the first main surface 101, the hole has a first cross sectional area, and from an intermediate point 132 the hole has a second cross sectional area. These two cross sectional-areas are of different dimensions, the first area suitably being larger than the second.

Thus, as can be seen in FIG. 1, a “ledge” 132 is created at the transition between the two diameters. The relationship between the area sizes can be the reverse, if, as suggested above, the relationship between the cross-sectional areas of the two parts 191, 192, of the cooling component are reversed.

With the main body now being thus prepared for receiving the first cooling component 190, with a through-hole and a ledge 132, the first cooling component is arranged in the through-hole. The reason for the ledge 132 and the different cross section of the cooling component 190 will now become apparent: the narrower section of the through-hole, i.e. the section with the second cross section, serves to receive or “brake” the cooling component 190 in the main body, the supporting structure of laminate.

In addition, the ledge 132 suitably also serves another purpose, apart from receiving or braking the cooling component: the laminate can be prepared as a two-part structure, a first part 130 having a through-hole with the first cross sectional area and a second part 133 having a through-hole with the second cross sectional area, the two parts then being joined together before the first cooling structure 190 is arranged in the body.

Thus, the ledge 132 will in this case also be an upper surface of the second part. On this upper surface, a circuit pattern 116 can be arranged, which will later be connected to a circuit pattern on the first main surface 101 of the PBA.

Suitably, the cooling component is fixed in the laminate structure by means of soldering to a laminate which is used for the circuit pattern 116. As an alternative, the cooling component 190 can be glued to the laminate.

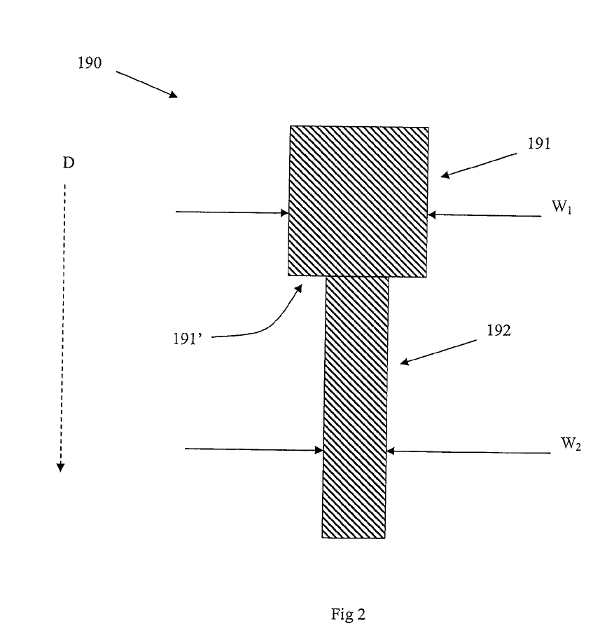

FIG. 2 shows the first cooling component 190. As shown here, the cooling component 190 is oblong, with a main direction of extension indicated by the arrow D, and comprises two parts, 191 and 192, which have different cross sectional areas, A₁ and A₂, with A₁ being larger than A₂. As mentioned previously, the relationship in size between the two parts can also be the opposite.

It can be pointed out here that the exact shape of the cooling component 190 can be varied in many ways, as will be realized from this description, but one principle which should be adhered to is that the cooling component should have a surface, in this case the “bottom” surface 191′ of the part 191 with the larger area, which can be received by a surface in the PBA or the laminate, in this case the ledge 132.

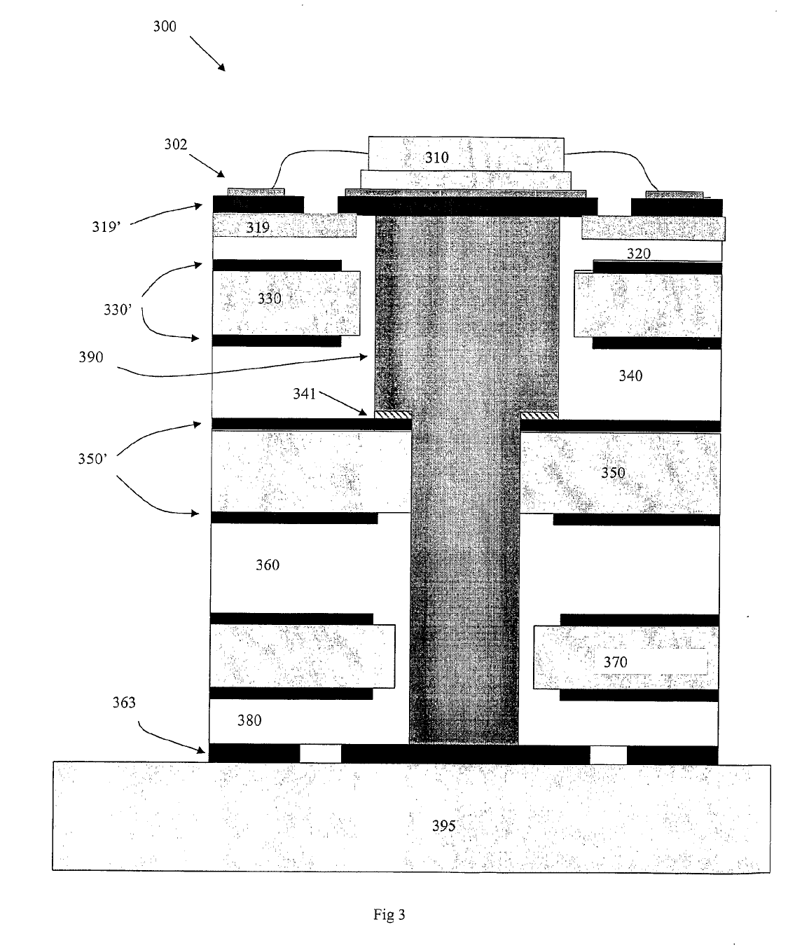

FIG. 1 shows a PBA according to the invention, but serves mainly to illustrate a principle behind the invention, FIG. 3 shows a PBA 300 which might be manufactured using this principle. The PBA 300 comprises a first cooling component 390, shaped and arranged as the corresponding component 190 in FIGS. 1 and 2. In addition, the PBA 300 comprises a plurality of layers, said layers alternatingly being, in a way which will be described later on, layers of a conducting material, a non-conducting laminate, and so called “prepreg”.

The material referred to consistently in this text as “prepreg” is used to fix rigid laminates together and to fill spacing between, for example, layers inside Printed Circuit Boards so that air pockets are essentially eliminated. Prepreg has a semi-cured chemistry, and can therefore be formed under special pre-defined combinations of heat, pressure and vacuum.

Once the prepreg chemistry has cured completely, it is fixed and will stay in that shape.

As an alternative to prepreg, so called bonding films can also used to fix different material layers to each other, and to fill spaces or cavities between material layers inside Printed Assembly Boards. Bonding films are also formed by heat, pressure and vacuum, but can be melted several times.

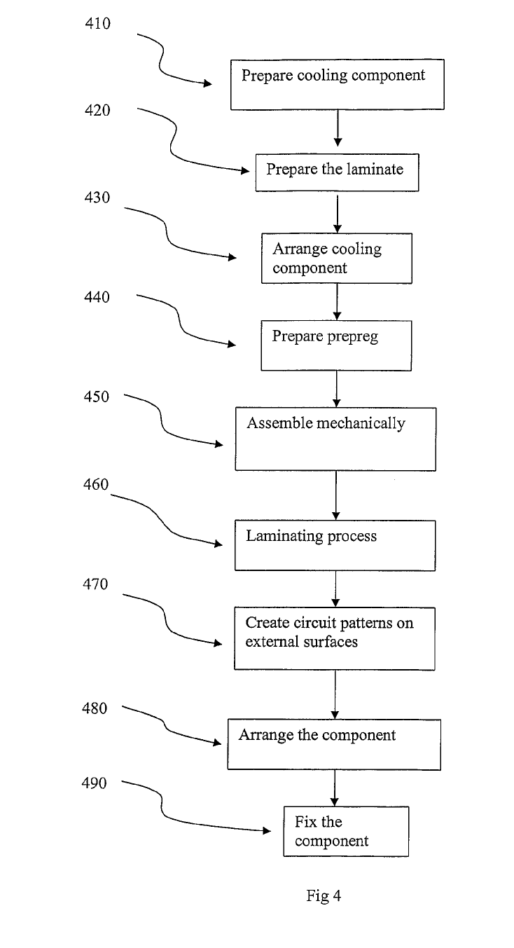

With the aid of FIG. 4, which is a flowchart outlining some of the major steps involved in the production of the PBA 300 of FIG. 3, the production of the PBA 300 will now be described, by means of which the various layers of the PBA 300 will also be understood. It should be pointed out that the steps shown in FIG. 4 and described below need not be carried out in the order shown and described, the important thing is the end result, i.e. the finished PBA 300.

As an initial step, block 410 in FIG. 4, the first cooling component 390 is prepared, i.e. given the shape shown and described above, and with the desired dimensions. The component should be made from a material which has a high capacity for conducting heat, for example copper, brass or other such metals or metal alloys. The shaping of the component can be carried out in a variety of ways which are known to those skilled in the field, for example by means of milling.

Next, block 420 in FIG. 4, a layer of a non-conducting laminate such as, for example, FR4, is prepared. The preparations in this case include making a hole or a “window” in the layer, said window in this case being slightly larger than A₂, i.e. the smaller of the two dimensions of the cooling component. The difference in size between the hole in the laminate and A₂ can suitably be in the area of 1-5%. The laminate layer prepared in this step will become the layer shown as 350 in FIG. 3.

Next, an optional step which is not shown in FIG. 4 can be carried out: if it is desired to have circuit patterns on one or both sides of the laminate layer 350, these patterns will now be arranged on the laminate. This is done by conventional means, such as for example etching or using photoresist, etc, and will thus not be described in further detail here. The circuit patterns created in this step are shown as 350′ in FIG. 3.

Next, the cooling component 390 is arranged in the window in the laminate layer 350 and fixed there. This is preferably done by means of soldering, using soldering material 341 deposited on the laminate 350 or on the circuit pattern 350′ arranged on the laminate. As an alternative to soldering, gluing can be used.

The next step is shown as block 440 in FIG. 4: a layer of so called “prepreg” is prepared. These preparations include giving the layer the desired dimensions, i.e. the width and length of the future PBA, as well as making a hole or a window in the layer of prepreg, said hole having a dimension corresponding to the larger cross sectional area A₁ of the cooling component 390. Suitably, the hole in the layer of prepreg is created by means of milling, although other processes are possible, for example drilling. The layer pf prepreg thus prepared will become the layer shown as 340 in FIG. 3.

The PBA 300 in FIG. 3 is shown as having a number of layers of non-conducting laminate, 350, 330, 319, 370, 363, as well as a number of layers of prepreg, 320, 340, 360, 380, where the layers of laminate are provided with circuit patterns on one or both of their sides. It will be appreciated by those skilled in the field that the PBA 300 can be provided with a more or less arbitrary number of layers arranged as in FIG. 3. For this reason, the preparation of all of the layers shown in FIG. 3 will not be described in detail here.

Accordingly, laminate layers 330, 319, and 370 will be prepared in the manner described above, as will prepreg layers 320, 360 and 380. Naturally, those layers which are to be arranged on that side of the cooling component which has the smaller dimension W₂ will be adapted for that.

Thus, a number of layers of prepreg and laminate will now have been prepared by giving them the desired mechanical dimensions, including the opening for the cooling component 390. As indicated in block 450 in FIG. 4, these layers are now assembled mechanically together with the laminate layer 350 to which the cooling component has already been attached, as described above.

The next step is to apply a so called “laminating process”, box 460 in FIG. 4, to the future PBA in order to fix the layers to each other permanently. This can, for example, be done in a so called “vacuum lamination oven”. The temperature in such an oven will vary depending on the kind of laminate which is used.

During the lamination process, the prepreg will become liquid, which explains the reason for making the opening in the laminate layers slightly larger than the width of the cooling component: during the laminating process, the future PBA, i.e. the layers which have been arranged mechanically in the proper order, is subjected to pressure from directions which correspond to the upper and lower sides of the PBA, i.e. the upper and lower main surfaces 101 and 102 of FIG. 1.

Due to this pressure, the liquefied prepreg will be pressed into the openings between the laminate layers and the cooling component, so that essentially all play is eliminated.

Following the laminating process, the PBA is removed from the vacuum oven and the prepreg is allowed to harden. If necessary, some surface processing can then be carried out in order to create smooth main surfaces of the PBA 300.

At this stage, if it is desired to have via holes in the PBA, these can be created by means of drilling, following which they are plated with a conducting metal, suitably copper. The plating process can (and usually will) also be used to create a layer of conducting metal on the top surface and usually also on the bottom surface of the PBA.

The next step, as shown in box 470 in FIG. 4, is to create circuit patterns on the upper and/or lower main surface of the PBA 300. The upper surface at this stage preferably consists of a non-conducting laminate covered with a thin layer of copper or some other conducting material, in which circuit patterns are created by well known conventional means, for example photolithographic methods.

As a final major step, boxes 480 and 490 in FIG. 4, the high power electronics component 310 for which the cooling component 390 is intended is arranged on the PBA, and fixed to the mentioned layer of a conducting material. The fixing can be done by such means as, for example, gluing or soldering, or by arranging an external component on the PBA or external to it, i.e. in a rack or similar arrangement, which exerts mechanical pressure on the electronics component 310 in the direction of the main surface of the PBA. By means of such a pressure component, the electronics component can be fixed securely on place, and be easy to remove and exchange.

As shown in FIG. 3, there will now be a cooling component 390 arranged directly beneath at least part of the high power component 310, and the cooling component will be able to conduct heat in a vertical direction of the PBA, i.e. from the first main surface to the second main surface.

One purpose of transporting heat in this direction emerges from FIG. 3: as shown in FIG. 3, the PBA is arranged in, for example a rack, where the lower main surface of the PBA comes into contact with a mechanical part 395 of the rack which can act as a heat sink. It is thus important that the cooling component emerges from the lower main surface, either directly, or as shown in FIG. 3, via a layer 363 of conducting material.

The invention is not limited to the examples of embodiments shown above, but can be varied freely within the scope of the appended claims. For example, the shape of the cooling component 190, 390, may be varied in a large number of ways while maintaining the ability of transporting heat.

1-8. (canceled)

9. A printed board assembly (PBA) comprising:
a first support layer having a first main surface;
a first layer of a conducting material arranged in a first pattern on the first main surface;
a first electronics component mounted on the first main surface; and
a first cooling component for transporting heat from the first electronics component to a cooling structure external to the PBA;
wherein:
the first electronics component is surface mounted on the PBA at least partially over the first cooling component;
the first cooling component is arranged integrally, by means of soldering, in the PBA to conduct heat in a direction which is essentially perpendicular to the first main surface of the first support layer;
the first cooling component is arranged so that an upper surface of the first cooling component is flush with the first main surface of the first support layer; and
the first layer of the conducting material is made to cover the upper surface of the first cooling component.

10. The PBA as recited in claim 9, wherein the first support layer is a two-part structure comprising:
a first part having a through-hole with a first cross sectional area; and
a second part having a through-hole with a second cross sectional area;
wherein the first cooling component includes two parts which have different cross sectional areas that match the different cross sectional areas of the two parts of the first support layer, so that a ledge in the PBA receives the first part of the cooling component.

11. The PBA as, recited in claim 10, wherein the upper surface of the second part of the first support layer has a circuit pattern arranged on it.

12. The PBA as recited in claim 9, wherein the first electronics component is surface mounted on the PBA by means of soldering, gluing, or applying pressure from an external component.

13. The PBA as recited in claim 9, wherein the first cooling component emerges on a lower main surface of the PBA.

14. A method of manufacturing a printed board assembly (PBA), comprising the steps of:
preparing an opening in a layer of a non-conducting laminate for receiving a first cooling component;
preparing the cooling component for being fitted into the opening in the laminate;
fitting the cooling component into the laminate;
preparing circuit patterns on at least a first main side of the laminate;
processing the laminate and the cooling component so that they together become a PBA;
fitting the cooling component into the laminate in a direction which is essentially perpendicular to a main surface of the laminate;
surface mounting a first electronics component on the PBA at least partially over the first cooling component;
wherein the method includes:
arranging the first cooling component so that a first surface of the first cooling component is flush with the first main surface of the laminate; and
arranging a first layer of a conducting material to cover the first surface of the first cooling component.

15. The method as recited in claim 14, wherein:
the laminate is prepared as a two-part structure, a first part having a through-hole with a first cross sectional area and a second part having a through-hole with a second cross sectional area; and
the first cooling component is includes two parts which have different cross sectional areas, said areas being made to match the different cross sectional areas of the two parts of the first support layer, so that a ledge in the PBA receives the first part of the cooling component.

16. The method as recited in claim 15, wherein a circuit pattern is arranged on the upper surface of the second part of the laminate.

17. The method as recited in claim 14, wherein the first electronics component is surface mounted to the board by means of soldering, gluing, or applying pressure from an external component.

18. The method as recited in claim 14, further comprising:
arranging the first cooling component so that a second surface of the first cooling component contacts a cooling structure external to the PBA, wherein the first cooling component transports heat from the first electronics component to the cooling structure.
